(19) United States
(12) Patent Application Publication
(10) Pub. No.: US 2010/0002115 A1
(43) Pub. Date: Jan. 7, 2010

(54) Method for Fabricating Large Photo-Diode Arrays

(76) Inventor: XinQiao Liu, Mountain View, CA (US)

Correspondence Address: THE LAW OFFICES OF CALVIN B. WARD, 18 CROW CANYON COURT, SUITE 305, SAN RAMON, CA, 94583, US

(21) Appl. No.: 12/168,017

(22) Filed: Jul. 3, 2008

(51) Int. Cl. H04N 5/335

(52) U.S. Cl. 348/308; 348/E05.091

(57) ABSTRACT

A photodetector array and method for making the same are disclosed. The photodetector array includes a two-dimensional array of pixels and a controller. Each pixel includes a photodetector and a readout circuit, the readout circuit coupling that pixel to a corresponding bit line when a readout signal is received on a corresponding row line. The controller generates the row selection commands and processes signals on the bit lines. The photodetector array is divided into a plurality of sub-chips fabricated on a semiconductor substrate and having a plurality of metal conductors overlying the substrate. The sub-chips include a plurality of slave sub-chips, each slave sub-chip includes a row decode circuit, and a plurality of the rows of pixels, the row decode circuit in one of the slave-sub-chips providing the readout signals on row lines in that sub-chip in response to one of the row selection commands.

### BACKGROUND OF THE INVENTION

Digital cameras utilize sensors that include a two-dimensional array of pixel sensors that measure the light at each point in an image to be recorded. In conventional cameras, the image is projected onto the pixel array by a lens, and hence, the size of the imaging array is less important since arrays of different physical sizes can be accommodated by altering the focal length of the lens. Since cost is a major concern in such cameras, smaller arrays are preferred, since the size of the array determines the cost.

However, there are applications in which the actual physical size of the pixels is important, and hence, the size of the chip must be increased beyond the size that would be used for an inexpensive camera. For example, in cameras that must function in low-light conditions, the physical size of the pixel must often be increased to allow the camera to operate correctly. In some astronomy applications, both the number of pixels and the size of each pixel must be increased to the point that the resultant chip is much larger than the size of the optimum die in CMOS fabrication systems.

Large dies are also required in digital photography for x-ray applications, particularly dental x-ray imaging. This type of digital imaging has the promise of providing images of equivalent quality as conventional x-ray film based systems at lower cost and lower x-ray exposures. An x-ray sensor for dental applications typically consists of a layer of scintillation material that is mounted in front of an image sensor that is sensitive in the visual range of wavelengths. The scintillation material converts the x-rays to photons in the range in question, and the photons are measured by the image sensor.

The imaging array is typically mounted in an assembly that replaces the conventional “winged” x-ray film that is inserted into the patient's mouth. The x-ray sensor has a tab that extends from the middle of the assembly. The patient bites down on the tab to hold the array into position behind the teeth to be imaged. The teeth are then irradiated from outside the patient's mouth and the x-rays that pass through the teeth are detected to form an image. The images generated by such devices are “shadow” images, and hence, the imaging array must be the same size as the portion of the patient's mouth that is being imaged. Accordingly, the imaging arrays must be substantially larger than the imaging arrays used in conventional cameras.

In addition, the vertical size of the imaging array must be matched to the size of the patient's mouth. Conventional x-ray film systems likewise have a tab on which the patient bites to hold the film in place. However, since the film is flexible, the film can bend somewhat to accommodate different size mouths. In addition, x-ray film is relatively inexpensive, and hence, different sizes of film inserts can be inventoried in the dentist's office to accommodate individuals with small mouths such as children. In contrast, the imaging arrays used in digital photography are rigid, and hence, the dentist must have a number of sensors of different sizes on hand.

Imaging arrays are constructed on conventional integrated circuit fabrication lines. The fabrication systems rely on lithography in which an image is projected onto an area of the silicon wafer that is to eventually become the die having the image sensor. The image is projected by passing the radiation from the source through a mask having clear and opaque areas that determine which areas on the surface are exposed. The various areas that are to become separate dies are exposed sequentially by moving the projector from die area to die area. As the feature size of the fabrication lines has decreased, the cost of these mask sets has become substantial. This cost represents a significant portion of the cost of the imaging arrays for high end scientific and medical imaging applications, since the number of such imaging systems is relatively small.

The cost of the mask sets is further increased by the size of the imaging arrays. Any given fabrication line has a maximum size image that can be projected in any one exposure. If the die being fabricated is larger than this area, a number of individual sub-exposures must be performed with each sub-exposure being shifted slightly such that the desired image is “stitched” together from the individual exposures. Each of these sub-images typically involves a different mask. The imaging array size needed for dental and other large focal plane applications is larger than the maximum single exposure die size for most fabrication lines. In addition, the dental imaging arrays must be constructed in a number of different sizes to accommodate differences in the size of the mouths of the patients, which further increases the number of masks that must be utilized to provide dental imaging arrays.

### SUMMARY OF THE INVENTION

The present invention includes a photodetector array and method for making the same. The photodetector array includes a two-dimensional array of pixels and a controller. The two-dimensional array of pixels is organized as a plurality of rows and columns of pixels. Each pixel in one of the columns is connected to a bit line corresponding to that column, and each pixel in one of the rows is connected to a row line corresponding to that row. Each pixel includes a photodetector and a readout circuit, the readout circuit coupling that pixel to the bit line corresponding to that pixel when a readout signal is received on the row line corresponding to that pixel. The controller generates the row selection commands and processes signals on the bit lines. The photodetector array is divided into a plurality of sub-chips fabricated on a semiconductor substrate and having a plurality of metal conductors overlying the substrate, the sub-chips include a plurality of slave sub-chips, each slave sub-chip includes a row decode circuit, and a plurality of the rows of pixels, the row decode circuit in one of the slave-sub-chips providing the readout signals on row lines in that sub-chip in response to one of the row selection commands on one of the metal conductors. In one aspect of the invention, the photodetector array includes a control sub-chip that includes a portion of the controller. The control sub-chip is coupled to a plurality of the bit lines, and each bit line includes a corresponding one of the metal conductors. In another aspect of the invention, the row decode circuit in one of the slave sub-chips includes a shift register having a shift in port, a shift out port, and a clock input port. The shift in port is coupled to the shift output port in an adjacent slave sub-chip through one of the metal conductors. In yet another aspect of the invention, the row decode circuit in one of the slave sub-chips includes a multiplexer that is connected to a plurality of the metal conductors. In a still further aspect of the invention, each pixel further includes a backup readout circuit, the backup readout circuit coupling that pixel to a backup bit line in response to a signal on a backup row line.

### BRIEF DESCRIPTION OF THE DRAWINGS

FIG. 1 is a top view of dental sensor 30.

FIG. 2 is a side view of dental sensor 30.

FIG. 3 is a block diagram of a prior art CMOS imaging array.

FIG. 4 illustrates an embodiment of a pixel array chip according to the present invention.

FIG. 5 illustrates the division of a pixel array chip such as that shown in FIG. 4 into sub-chips that are fabricated with three mask sets.

FIG. 6 is a more detailed view of one of the sub-chips.

FIG. 7 is a more detailed view of an embodiment of a sub-chip that utilizes a multiplexer in place of a shift register.

FIG. 8 illustrates an imaging chip according to another embodiment of the present invention.

FIG. 9 illustrates one pixel in an imaging array according to one aspect of the present invention.

### DETAILED DESCRIPTION OF THE PREFERRED EMBODIMENTS OF THE INVENTION

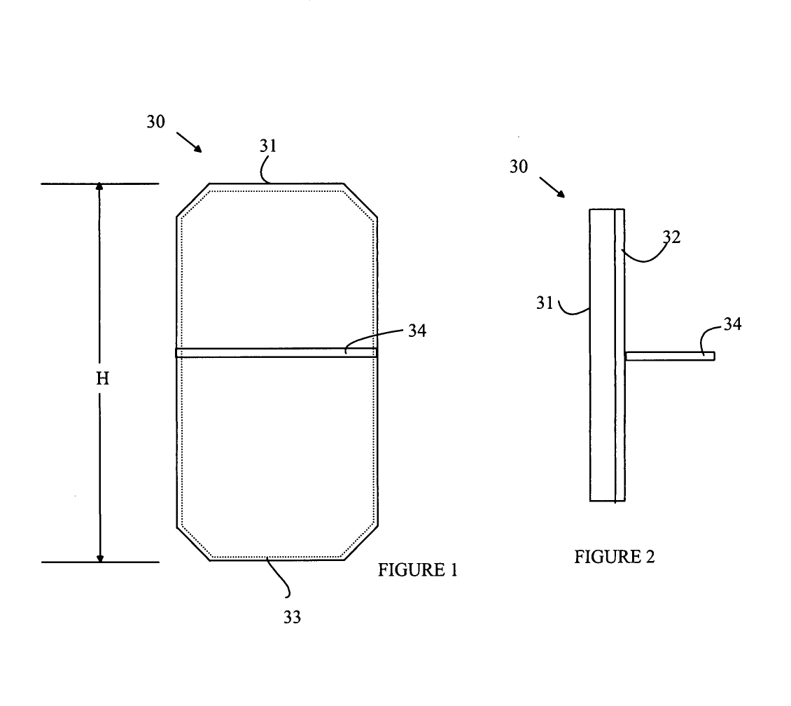

The manner in which the present invention provides its advantages can be more easily understood with reference to FIGS. 1 and 2, which illustrate one configuration for a dental sensor. FIG. 1 is a top view of sensor 30, and FIG. 2 is a side view of sensor 30. Sensor 30 is preferably constructed on a single die 31 with the imaging array 33 positioned in the middle of the die. The sensor utilizes a scintillation layer 32 to convert the x-rays to visible light that is recorded by imaging array 33. The sensor is positioned in the patient's mouth with the aid of a member 34 that is gripped between the teeth of the patient. The height, H, of the sensor must be sufficient to cover both the upper and lower teeth of the patient, but not so large as to cause the patient discomfort when the patient bites down on member 34. In this embodiment, the corners of the sensor are preferably chamfered to prevent patient discomfort arising from a sharp corner being forced against the patient's gums or one of the soft surfaces in the patient's mouth.

As noted above, H depends on the size of the oral cavity of the patient when the patient's mouth is closed. If H is too large, the sensor will cut into the top and bottom surfaces of the oral cavity. If H is too small, part of the image of the teeth and gums will be lost. Hence, a dentist must have a number of different dental sensors having different H values to accommodate the mix of patients seen in the dentist's office.

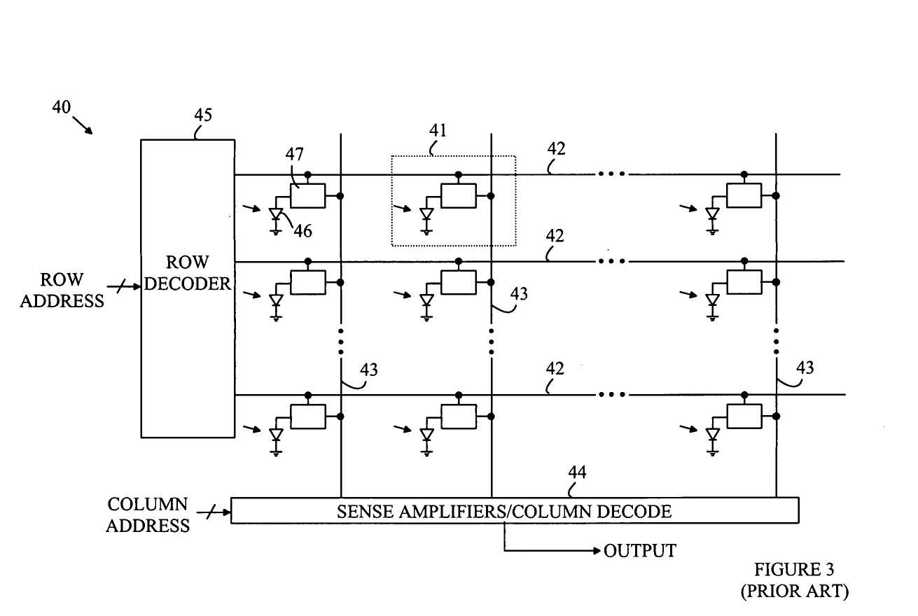

Refer now to FIG. 3, which is a block diagram of a prior art CMOS imaging array. Imaging array 40 is constructed from a rectangular array of pixel cells 41. Each pixel cell includes a photodiode 46 and an interface circuit 47. The details of the interface circuit depend on the particular pixel design. However, all of the pixel circuits include a gate that is connected to a row line 42 that is used to connect that pixel to a bit line 43. The specific row that is enabled at any time is determined by a bit address that is input to a row decoder 45. The row select lines are a parallel array of conductors that run horizontally in the metal layers over the substrate in which the photodiodes and interface circuitry are constructed. As noted above, row decoder 45 has a length that is equal to that of the vertical dimension of the pixel array, since all of the row conductors must terminate on the row decoder.

The various bit lines terminate in a column processing circuit 44 that typically includes sense amplifiers and column decoders that are used to convert the signals on the bit lines to either digital or analog output signals that are then readout one at a time by the column decoders. The bit lines are a parallel array of conductors that run vertically in the metal layers over the substrate in which the photodiode and interface circuitry are constructed. Each sense amplifier reads the signal produced by the pixel that is currently connected to the bit line processed by that sense amplifier. The sense amplifiers may generate a digital output signal by utilizing an analog-to-digital converter (ADC). At any given time, a single pixel cell is readout. The specific column that is readout is determined by a column address that is utilized by a column decoder to connect the sense amplifier/ADC output from that column to circuitry that is external to the imaging array. The imaging array shown in FIG. 3 is rectangular. In such imaging arrays, the row decode circuitry is located near one of the vertical edges of the die, and the column decode circuitry is located near one of the horizontal edges of the die.

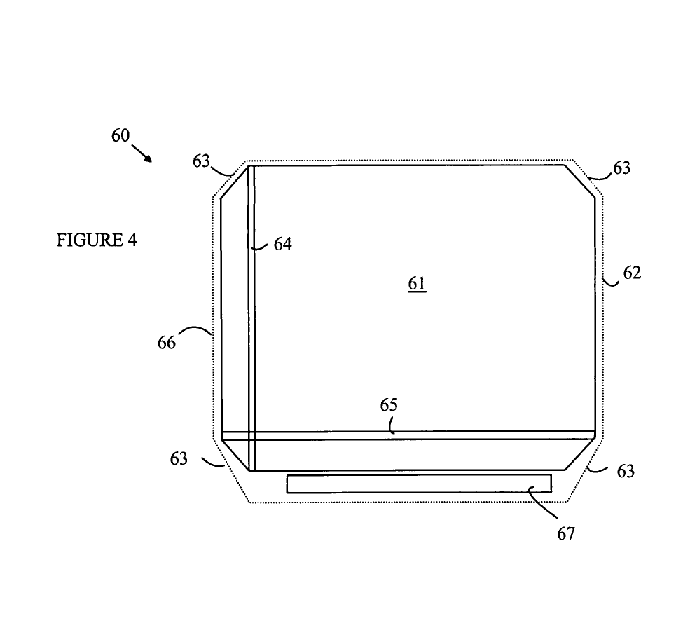

To accommodate the beveled edges described above, the row and column circuitry can be moved to a location internal to the photodiode array as shown in FIG. 4. FIG. 4, illustrates an embodiment of a pixel array chip according to the present invention. Pixel array chip 60 is constructed on a die 62 whose corners 63 have been chamfered for patient comfort. Pixel array chip 60 includes a pixel array 61 having a plurality of rows and columns of CMOS photodiode elements that are addressed via a row encoder 64 and a column encoder 65 that includes the sense amplifiers for reading the output of the individual pixel elements. Row encoder 64 is placed as close to edge 66 as possible and still span the entire height of pixel array 61. Similarly, column encoder 65 is placed as close as possible to the bottom edge of die 62 and still span the entire width of pixel array 61. The additional logic circuits are placed in the silicon substrate in region 67, which is laid out on active layers of the substrate and metal layers that overlie the substrate. The input-output pads for connecting pixel array chip 60 to external circuitry are deposited on the two top most metal layers over region 67. This arrangement allows the row and column decoders to extend to the edges of the die, and hence, avoids problems associated with the chamfered corners.

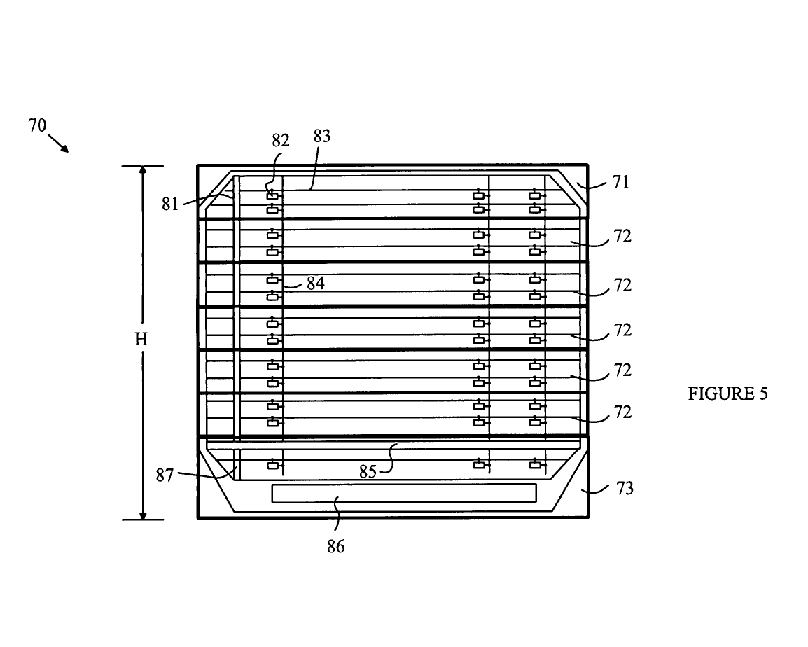

Refer now to FIG. 5, which illustrates the division of a pixel array chip such as that shown in FIG. 4 into sub-chips that are fabricated with three mask subsets. Pixel array chip 70 is constructed from three types of sub-chips. Each sub-chip includes a portion of the imaging array consisting of a plurality of rows of pixels and the row lines and row decode circuitry used to connect those pixels to the corresponding bit lines. In addition, each sub-chip includes a portion of the bit lines for each of the columns of pixels. An exemplary pixel is labeled at 82. Exemplary bit lines and row lines are labeled at 83 and 84, respectively.

The first sub-chip 71 includes the portion of the imaging array that has the top chamfered corners. The portion of the row decoder that is used to access the rows of pixels on this sub-chip is shown at 81. Portions of the bit lines that connect columns of pixels in this sub-chip are also provided within the sub-chip.

The second type of sub-chip is shown at 73. Sub-chip 73 includes a portion of the imaging array having the bottom chamfered corners, the portion of the row decoder used to access the rows of pixels in this sub-chip being shown at 87. Sub-chip 73 also includes the column decode circuitry 85 on which the various bit lines terminate. Finally, sub-chip 73 also includes the control logic 86.

The third type of sub-chip is shown at 72. Sub-chip 72 includes a rectangular portion of the imaging array and the bit and row lines that service the pixels in the sub-chip. Sub-chip 72 also includes the portion of the row decoder needed to access the pixels in that sub-chip. The number of sub-chips of this type depends on the height, H, of the pixel chip. By varying the number of sub-chips of this type, chips of varying heights can be fabricated without requiring additional sub-sets of masks.

The above-described sub-chips are designed in such a way that the combined total area of their corresponding mask subsets is less than the maximum mask set area that can be exposed in the fabrication system. The maximum mask set area is typically 25 mm×33 mm. In the above-mentioned example, the physical size of pixel array chip 70 is larger than the maximum mask set area. Hence, without the present invention, pixel array chip 70 would require two or more mask sets to make, hence, have a significantly higher total cost.

Instead of using one to one area ratio between the physical sensor chip and the mask set, which will result in more than one mask sets, the present invention repeatedly uses sub-chip 72 that requires one mask sub-set to cover a much larger physical chip area, such that all mask sub-sets will not exceed maximum single set area of 25 mm×33 mm.

For each masking step during fabrication, the camera system selects the mask subset corresponding to the sub-chip that is to be exposed next and exposes that sub-chip. The camera then moves over the next sub-chip, selects the correct mask subset, and exposes that sub-chip and so on.

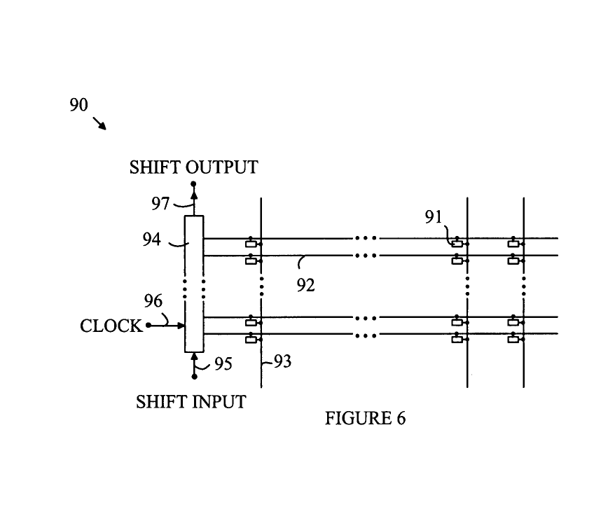

Refer now to FIG. 6, which is a more detailed view of one of the sub-chips. Sub-chip 90 could be utilized for either sub-chip 71 or 72 shown in FIG. 5. Sub-chip 90 includes an array of pixels such as pixel 91. Each pixel is connected to a row-line such as row line 92 and a bit line such as bit line 93. The charge stored in a pixel is transferred to the bit line corresponding to that pixel when a signal is applied to the row line connected to that pixel.

In general, only one row of pixels is connected to the bit lines at a time, and hence, the row decoder can be implemented as a shift register in which each row line terminates on the output of one of the cells in the shift register. The row lines are connected to a shift register 94 in sub-chip 90. Shift register 94 receives an input on line 95 that is shifted into shift register 94 in response to a clock signal on input line 96. The output of the last cell in shift register 94 is presented on the shift out line 97. Shift input line 95 is connected to the shift output line in an adjacent sub-chip. Similarly the shift output line 97 is connected to the shift input line in an adjacent sub-chip, except in the case of sub-chip 71 shown in FIG. 5.

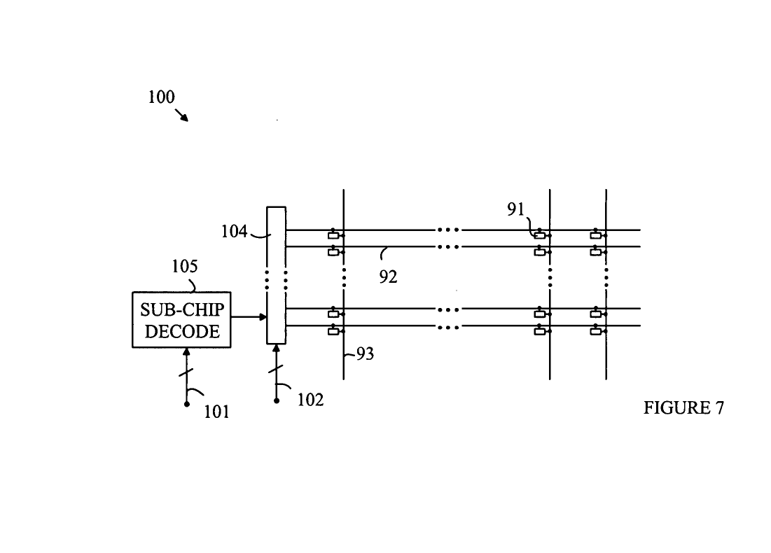

The sub-chip design shown in FIG. 6 is adapted for imaging sensors in which the image is readout in order, one line at a time. However, in some applications, access to the rows of pixels is required on a more random basis. Refer now to FIG. 7, which is a more detailed view of an embodiment of a sub-chip that utilizes a multiplexer in place of the shift register utilized in sub-chip 90 discussed above. Sub-chip 100 has a multiplexer 104 that selects one of the row lines in response to an address signal on buses 101 and 102 that are routed to all of the sub-chips. The value on bus 101 selects the sub-chip to be activated, and the value on bus 102 selects the specific line within that sub-chip. To minimize the number of lines in bus 101, each sub-chip has a separate decoder 105 that generates a chip enable signal that is input to multiplexer 104.

It should be noted that all of the active circuitry on each sub-chip is contained on that sub-chip, i.e., none of the active circuitry is split between sub-chips. All of the connections between the various sub-chips can be made through the metal layers, and hence, small alignment errors between the sub-chips can be tolerated.

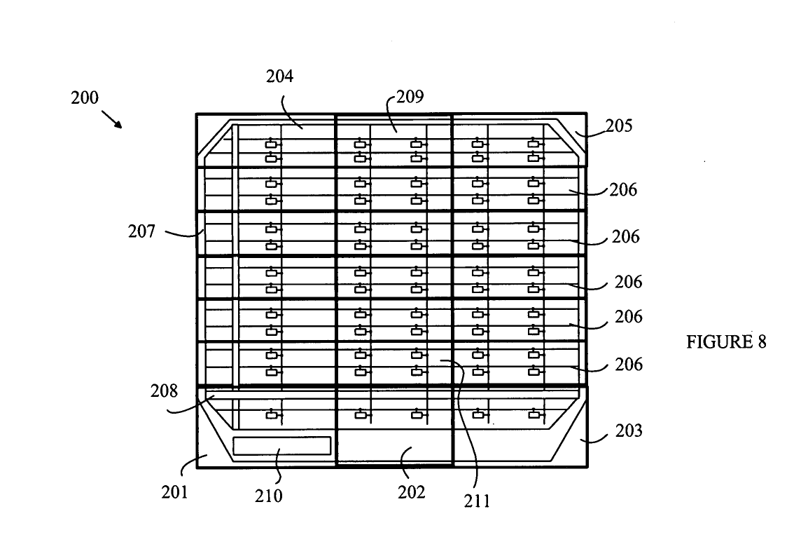

The above-described embodiments of the present invention utilize a sub-chip design in which the width of the final imaging chip is the same as the maximum width of a sub-chip. However, the final imaging chips that are larger than the maximum sub-chip size in both dimensions can be fabricated. Refer now to FIG. 8, which illustrates an imaging chip according to another embodiment of the present invention. Imaging chip 200 also has chamfered corners. Imaging chip 200 is constructed from 9 sub-chips. Sub-chips 204, 207, and 201 include the row selection circuitry, the chamfered corner sections for one side of the imaging chip, the controller 210, and the portion of the column processing circuitry 208 that services chips 204, 207, and 201. The number of sub-chips 207 depends on the height of imaging array 200. Sub-chips 202 and 203 contain the remaining column processing circuitry. Sub-chip 203 contains the lower right chamfered corner and the portion of the pixel array near that corner. Sub-chip 205 includes the upper right chamfered corner and the portion of the pixel array near that corner. Sub-chip 206 is a rectangular array of pixels and the associated sections of the bit lines and row lines that service those pixels. Sub-chip 206 also includes the chip right side edge. Sub-chip 209 is a rectangular array of pixels and the associated sections of the bit lines and row lines that service those pixels. Sub-chip 209 also includes the chip top side edge. Sub-chip 211 is a rectangular array of pixels and the associated sections of the bit lines and row lines that service those pixels.

Sub-chip 200 only has one column of sub-chips in the middle of the array, i.e., the column of sub-chips containing sub-chip 202, sub-chip 211, and sub-chip 209. However, there may be an arbitrary number of such columns.

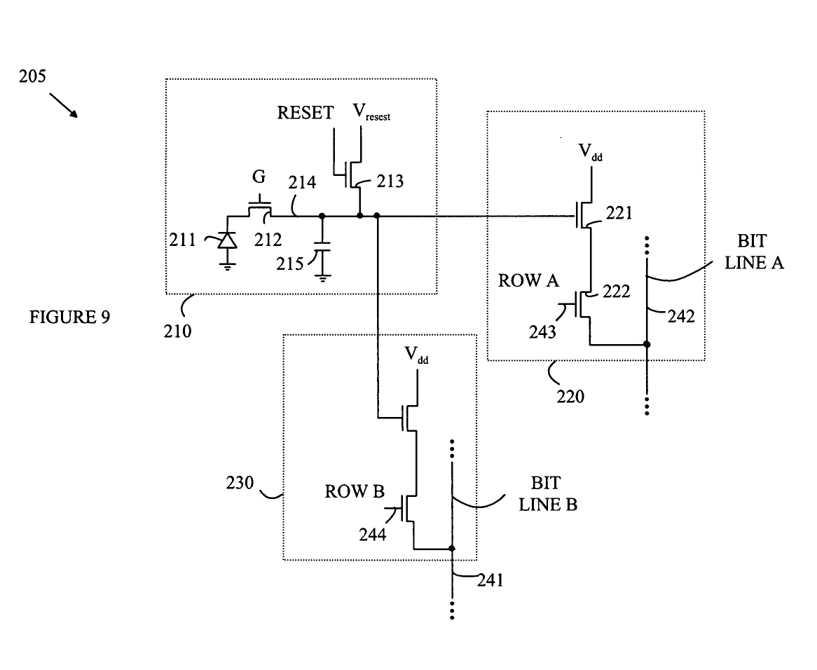

The increased size of the final chip can lead to yield problems in the fabrication of the die. As the chip size is increased, the probability that one or more pixels will be defective or one or more of the bit lines or row lines is defective increases. Hence, providing some degree of redundancy in the imaging array is desirable. In one aspect of the present invention, redundant bit lines and/or row select lines are utilized. Refer now FIG. 9, which illustrates one pixel in an imaging array according to this aspect of the present invention. Pixel 205 includes a light to charge conversion circuit 210 and two output circuits shown at 220 and 230. Light to charge conversion circuit 210 includes a photodiode 211 that is coupled to a node 214 by gate 212. Prior to each exposure, the potential on photodiode 211 and node 214 is reset to a predetermined potential by placing gate 213 in a conducting state while gate 212 is also in a conducting state. After an exposure to light, the charge stored on photodiode 211 is transferred to node 214 by placing gate 212 in the conducting state. Node 214 has a parasitic capacitance 215 that converts charge transferred to node 214 from photodiode 211 to a voltage that is readout by output circuits 220 and 230.

Each of the output circuits includes a source follower transistor and a gate transistor. The source follower and gate transistors in output circuit 220 are shown at 221 and 222, respectively. Each of the gate transistors couples the output of the corresponding source follower transistor to a corresponding bit line in response to a signal of a row line corresponding to that output circuit. The row lines corresponding to output circuits 220 and 230 are shown at 243 and 244.

In an imaging array that utilizes pixel 205, each of the bit lines in the imaging array shown in FIG. 5 is replaced by two bit lines that are separated spatially. One of these bit lines may be viewed as a backup bit line that provides a connection to the column processing circuitry in the event the other bit line is damaged by fabrication imperfection. The bit lines to which pixel 205 is connected are shown at 241 and 242. Similarly, each of the row lines in the imaging array has been replaced by two row lines that are separated spatially to provide a backup row line. Hence, a break in one of the bit lines or row lines does not prevent the pixel from being read out. The redundant row lines can be driven from a common output line in the row decoder. Similarly, the redundant bit lines can be connected to the same bit line processing circuit in the column decode circuitry.

The above-described embodiments of the present invention utilize an array of photodiodes. However, embodiments in which the photodiodes are replaced by other forms of photodetectors could also be constructed. For example, the photodiodes could be replaced by phototransistors.

Various modifications to the present invention will become apparent to those skilled in the art from the foregoing description and accompanying drawings. Accordingly, the present invention is to be limited solely by the scope of the following claims.

What is claimed is:

1. A photodetector array comprising:
a two-dimensional array of pixels organized as a plurality of rows and columns of pixels, each pixel in one of said columns being connected to a bit line corresponding to that column and each pixel in one of said rows being connected to a row line corresponding to that row, each pixel comprising a photodetector and a readout circuit, said readout circuit coupling that pixel to said bit line corresponding to that pixel when a readout signal is received on said row line corresponding to that pixel; and
a controller that generates row selection commands and processes signals on said bit lines, wherein
said photodetector array is divided into a plurality of sub-chips fabricated on a semiconductor substrate and having a plurality of metal conductors overlying said substrate, said sub-chips comprising a plurality of slave sub-chips, each slave sub-chip comprising a row decode circuit, and a plurality of said rows of pixels, said row decode circuit in one of said slave-sub-chips providing said readout signals on row lines in that sub-chip in response to one of said row selection commands on one of said metal conductors.

2. The photodetector array of claim 1 further comprising a control sub-chip that includes a portion of said controller, said control sub-chip being coupled to a plurality of said bit lines, each bit line comprising a corresponding one of said metal conductors.

3. The photodetector array of claim 2 wherein said row decode circuit in one of said slave sub-chips comprises a shift register having a shift in port, a shift out port, and a clock input port, said shift in port being coupled to said shift output port in an adjacent slave sub-chip through one of said metal conductors.

4. The photodetector array of claim 2 wherein said row decode circuit in one of said slave sub-chips comprises a multiplexer that is connected to a plurality of said metal conductors.

5. The photodetector array of claim 1 wherein each pixel further comprises a backup readout circuit, said backup readout circuit coupling that pixel to a backup bit line in response to a signal on a backup row line.

6. The photodetector array of claim 1 wherein one row of pixels in one of said slave sub-chips has fewer pixels than another row in said slave sub-chip, said row having fewer pixels being located along an edge of said photodetector array.

7. A method for fabricating a photodetector array comprising: a two-dimensional array of pixels organized as a plurality of rows and columns of pixels, each pixel in one of said columns being connected to a bit line corresponding to that column and each pixel in one of said rows being connected to a row line corresponding to that row, each pixel comprising a photodetector and a readout circuit, said readout circuit coupling that pixel to said bit line corresponding to that pixel when a readout signal is received on said row line corresponding to that pixel; and a controller that generates row selection commands and processes signals on said bit lines, said method comprising:
dividing said photodetector array into a plurality of sub-chips fabricated on a semiconductor substrate, wherein said photodetector array is fabricated in a fabrication system utilizing masks having a maximum single mask area, and wherein said photodetector array is fabricated by repeating a plurality of mask exposures utilizing a mask set containing a plurality of masks for each exposure, said plurality of masks having a total mask area, said total mask area being less than said maximum single mask area.

8. The method of claim 7 wherein each mask in said mask set defines one of said sub-chips, said sub-chips being connected electrically through metal conductors fabricated in layers overlying said substrate.
